(19) United States
(12) Patent Application Publication
(10) Pub. No.: US 2026/0118382 A1
(43) Pub. Date: Apr. 30, 2026

(54) PROBE ADAPTER AND MEASUREMENT SYSTEM

(71) Applicant: RIGOL TECHNOLOGIES CO., LTD., Suzhou (CN)

(72) Inventors: Kai YANG, Suzhou (CN); Liming WANG, Suzhou (CN); Yue WANG, Suzhou (CN)

(73) Assignee: RIGOL TECHNOLOGIES CO., LTD., Suzhou (CN)

(21) Appl. No.: 19/003,412

(22) Filed: Dec. 27, 2024

(30) Foreign Application Priority Data
Feb. 1, 2024 (CN) CN202410146765X

(51) Int. Cl. G01R 1/067; G01R 13/02; G01R 35/00

(52) U.S. Cl. CPC G01R 1/06788; G01R 35/005; G01R 13/0218

(57) ABSTRACT

The present disclosure relates to a probe adapter and a measurement system, including: a first interface, configured to be electrically connected to a probe; a second interface, configured to be electrically connected to a measuring instrument; signal transmission lines, including first and second signal transmission lines, and a line selection switch, where the first and second signal transmission lines are both located between the first interface and the second interface, and the line selection switch is configured to select the first signal transmission line or the second signal transmission line to conduct the first interface and the second interface; and a signal conditioning circuit, located on the second signal transmission line, and configured to adjust an impedance of a measured signal to match an input impedance of the measuring instrument, and/or adjust an amplitude of the measured signal to match a measurement range of the measuring instrument.

### CROSS-REFERENCE TO RELATED APPLICATION

The present disclosure claims priority to Chinese patent application No. 202410146765X, filed on Feb. 1, 2024, entitled “PROBE ADAPTER AND MEASUREMENT SYSTEM”, which is incorporated herein by reference in its entirety.

### TECHNICAL FIELD

The present disclosure relates to the technical field of an oscilloscope, and in particular, to a probe adapter and a measurement system.

### BACKGROUND

A digital oscilloscope has unique advantages such as waveform triggering, storage, display, measurement, and waveform data analysis and processing, and is an indispensable tool for designing, manufacturing, and repairing electronic devices. With the rapid development of electronic devices, engineers need the best tools to quickly and accurately solve measurement challenges they face. As the eyes for engineers, the digital oscilloscope is critical in facing current tricky measurement challenges. In addition, compared with an analog oscilloscope, the digital oscilloscope has smaller errors, making its application increasingly widely.

A high-bandwidth oscilloscope has a larger application range, and is therefore used more commonly. However, the high-bandwidth oscilloscope is basically an oscilloscope with a low input impedance, for example, an input impedance of 50 ohms, and has an input port being mostly a radio frequency interface terminal or customized interface terminal, making it impossible to use an ordinary high impedance passive probe or active probe.

### SUMMARY

In view of this, embodiments of the present disclosure provide a probe adapter and a measurement system to resolve at least one problem in the BACKGROUND.

According to a first aspect, an embodiment of the present disclosure provides a probe adapter for a measuring instrument, including:
a first interface, configured to be electrically connected to a probe to receive a measured signal;
a second interface, configured to be electrically connected to a measuring instrument to input the measured signal into the measuring instrument;
signal transmission lines, including a first signal transmission line, a second signal transmission line, and a line selection switch, where the first signal transmission line and the second signal transmission line are both located between the first interface and the second interface, and the line selection switch is configured to select the first signal transmission line to conduct the first interface and the second interface or select the second signal transmission line to conduct the first interface and the second interface; and
a signal conditioning circuit, located on the second signal transmission line, and configured to adjust an impedance of the measured signal to match an input impedance of the measuring instrument, and/or configured to adjust an amplitude of the measured signal to match a measurement range of the measuring instrument.

Optionally, the probe adapter further includes:
a control part, configured to control the line selection switch to select the first signal transmission line or the second signal transmission line to conduct the first interface and the second interface, where the line selection switch is communicatively connected to the control part.

Optionally, the control part is specifically configured to:
acquire a type of the probe connected to the first interface, in a case that the type of the probe connected to the first interface is a first probe, control the line selection switch to select the first signal transmission line to conduct the first interface and the second interface, and in a case that the type of the probe connected to the first interface is a second probe, control the line selection switch to select the second signal transmission line to conduct the first interface and the second interface.

Optionally, the signal conditioning circuit includes:
a gain amplifier, configured to adjust the impedance of the measured signal to match the input impedance of the measuring instrument, and/or configured to adjust the amplitude of the measured signal to match the measurement range of the measuring instrument; and
a differential amplifier, configured to convert a differential signal outputted by the gain amplifier into a single-ended signal to match a type of the measured signal of the measuring instrument.

Optionally, the probe adapter further includes:
a recognition circuit, communicatively connected to both the control part and the first interface, where the recognition circuit is configured to recognize a type of the probe connected to the first interface and send the type to the control part.

Optionally, the probe adapter further includes:
a calibration circuit, communicatively connected to both the control part and the first interface, where the calibration circuit is configured to calibrate an offset of a signal outputted by the probe connected to the first interface and adjust a direct current component of the measured signal to match a display interface of the measuring instrument.

Optionally, the probe adapter further includes:
a first selection switch, including a first fixed end and a first selection end, where the first fixed end is electrically connected to the first interface, and the first selection end is electrically connected to one of the signal transmission lines according to an instruction of the control part; and
a second selection switch, including a second fixed end and a second selection end, where the second fixed end is electrically connected to the second interface, and the second selection end is electrically connected to one of the signal transmission lines according to an instruction of the control part.

Optionally, the probe adapter further includes:
a third interface, configured to acquire electric energy of the measuring instrument; and
a power supply line, having one end electrically connected to the third interface and the other end electrically connected to the first interface to transmit the electric energy to the probe.

Optionally, an output impedance of the first probe is 50 ohms, and an output impedance of the second probe is 1 megohm.

According to a second aspect, an embodiment of the present disclosure provides a measurement system, including a measuring instrument, a probe, and a probe adapter connected between the measuring instrument and the probe, where
the probe adapter is any probe adapter described above.

The probe adapter and measurement system include: a first interface, configured to be electrically connected to a probe to receive a measured signal; a second interface, configured to be electrically connected to a measuring instrument to input the measured signal into the measuring instrument; signal transmission lines, including a first signal transmission line, a second signal transmission line, and a line selection switch, where the first signal transmission line and the second signal transmission line are both located between the first interface and the second interface, and the line selection switch is configured to select the first signal transmission line to conduct the first interface and the second interface or select the second signal transmission line to conduct the first interface and the second interface; and a signal conditioning circuit, located on the second signal transmission line, and configured to adjust an impedance of the measured signal to match an input impedance of the measuring instrument, and/or configured to adjust an amplitude of the measured signal to match a measurement range of the measuring instrument. As can be seen, for the probe adapter and the measurement system in the embodiments of the present disclosure, two signal transmission lines, namely, the first signal transmission line and the second signal transmission line, are disposed between the first interface and the second interface of the probe adapter, and the signal conditioning circuit is disposed on the second signal transmission line and is configured to adjust the impedance and/or the amplitude of the measured signal to correspondingly match the input impedance and/or the measurement range of the measuring instrument. In this way, a high-bandwidth oscilloscope can use an ordinary high impedance passive probe and/or active probe through the probe adapter, and it is not necessary to change probe adapters for different probes.

The additional aspects and advantages of the present disclosure are partially provided in the following description and partially become obvious from the following description or understood through the practice of the present disclosure.

### BRIEF DESCRIPTION OF THE DRAWINGS

The accompanying drawings described herein are used to provide a further understanding of the present disclosure, and constitute a part of the present disclosure. The schematic embodiments of the present disclosure and the description thereof are used to explain the present disclosure and do not constitute an inappropriate limitation to the present disclosure. In the accompanying drawings:

FIG. 1 is a schematic structural diagram of a probe adapter according to an embodiment of the present disclosure;

FIG. 2 is a schematic structural diagram of a probe adapter according to another embodiment of the present disclosure;

FIG. 3 is a schematic structural diagram of a probe adapter according to still another embodiment of the present disclosure;

FIG. 4 is a schematic structural diagram of a calibration circuit according to an embodiment of the present disclosure;

FIG. 5 is a schematic structural diagram of a measurement system according to an embodiment of the present disclosure;

FIG. 6 is a schematic structural diagram of a measurement system when a measuring instrument is an oscilloscope;

FIG. 7 is a schematic structural diagram of a probe adapter in FIG. 6; and

FIG. 8 is a schematic structural diagram of a first interface to a third interface in the probe adapter in FIG. 7.

### REFERENCE NUMERALS

11. first interface; 12. second interface; 13. third interface; 21. first signal transmission line; 22. second signal transmission line; 24. signal conditioning circuit; 241. gain amplifier; 242. differential amplifier; 26. first selection switch; 27. second selection switch; 31. control part; 32. recognition circuit; 33. calibration circuit; 34. power module; 60. probe; and 70. measuring instrument.

### DETAILED DESCRIPTION

To make the technical solutions and beneficial effects of the present disclosure more obvious and comprehensible, the following is a detailed description by way of enumerating specific embodiments. The accompanying drawings are not necessarily drawn to scale, and the local features may be enlarged or reduced to show the details of the local features more clearly. Unless otherwise defined, the technical and scientific terms used herein have the same meanings as those used in the technical field to which the present disclosure belongs.

In the description of the present disclosure, the terms “center”, “longitudinal”, “transverse”, “length”, “width”, “thickness”, “height”, “up”, “down”, “front”, “back”, “left”, “right”, “vertical”, “horizontal”, “top”, “bottom”, “inner”, “outside”, “clockwise”, “counterclockwise”, and the like indicate orientation or positional relationships based on those shown in the accompanying drawings, which is only for the purpose of facilitating a simplified description of the present disclosure, but do not indicate that the apparatus or element referred to must have a particular orientation or be constructed and operated in a particular orientation, i.e., it is not to be construed as a limitation of the present disclosure.

In the present disclosure, the terms “first” and “second” are used only for the purpose of clarity of description and are not to be construed as the relative importance of the indicated features or the number of indicated technical features. Therefore, a feature defined with the terms “first” and “second” may expressly include at least one such feature. In the description of the present disclosure, “plurality” means at least two, e.g., two, three, etc., and “several” means at least one, e.g., one, two, three, etc., unless otherwise expressly and specifically limited.

In the present disclosure, unless otherwise expressly defined, the terms “mount”, “connect”, “connection”, “fix”, and “dispose”, etc., should be understood in a broad sense, for example, “connection” can be a fixed connection, a detachable connection, or an integrated connection; or be a mechanical connection, or an electrical connection; or be connected directly or through an intermediate medium, or be an internal connection or an interaction relationship between two elements. A person of ordinary skill in the art may understand specific meanings of the foregoing terms in the present disclosure according to specific cases.

In the present disclosure, unless otherwise expressly limited, the first feature being “on”, “above”, “over”, “upon”, “under”, “below”, “underneath”, or “beneath” the second feature can be that the first feature and the second feature are in direct contact, or the first feature and the second feature are in indirect contact through an intermediate medium. In addition, the first feature being “above”, “over” or “upon” the second feature may be the case that the first feature is directly or obliquely over the second feature, or merely indicates that the first feature is at a higher horizontal height than the second feature. The first feature being “under”, “below”, or “underneath” the second feature may be the case that the first feature is directly or obliquely under the second feature, or merely indicates that the first feature is at a lower horizontal height than the second feature.

To understand the present disclosure thoroughly, detailed steps and detailed structures will be proposed in the following description to set forth the technical solution of the present disclosure. The detailed descriptions of the preferred embodiments of the present disclosure are as follows. However, the present disclosure may also have other implementations in addition to these detailed descriptions.

The inventor found in the technical research and development that an input port of a high-bandwidth oscilloscope is mostly a radio frequency interface terminal or customized interface terminal, making it impossible to use an ordinary high impedance passive probe, active probe, or the like. Therefore, the use range of the high-bandwidth oscilloscope is limited. By using a probe adapter to interface with an ordinary high impedance passive probe and an active probe, a plurality of probe adapters need to be purchased, resulting in increased costs of purchase and reduced efficiency of use. Moreover, in the process of changing a probe adapter, it is also easy to make mistakes, which may cause damage to an oscilloscope, a probe or a probe adapter, or lead to a wrong measurement result.

Therefore, the inventor has proposed the following technical solution through further research and development.

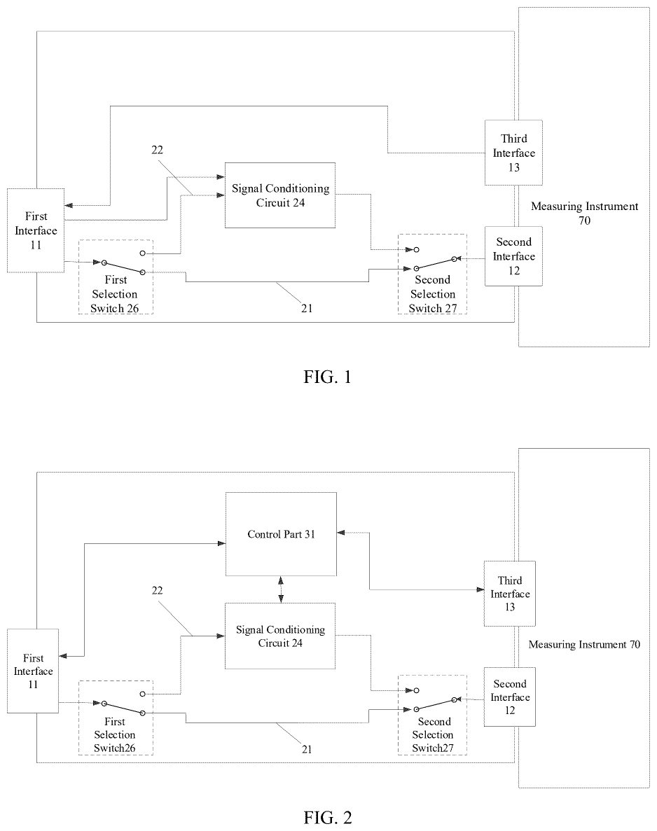

An embodiment of the present disclosure provides a probe adapter, referring to FIG. 1, including:
a first interface 11, configured to be electrically connected to a probe 60 to receive a measured signal;
a second interface 12, configured to be electrically connected to a measuring instrument 70 to input the measured signal into the measuring instrument 70;
signal transmission lines, including a first signal transmission line 21, a second signal transmission line 22, and a line selection switch, where the first signal transmission line 21 and the second signal transmission line 22 are both located between the first interface 11 and the second interface 12, and the line selection switch is configured to select the first signal transmission line 21 to conduct the first interface 11 and the second interface 12 or select the second signal transmission line 22 to conduct the first interface 11 and the second interface 12; and
a signal conditioning circuit 24, located on the second signal transmission line 22, and configured to adjust an impedance of the measured signal to match an input impedance of the measuring instrument, and/or adjust an amplitude of the measured signal to match a measurement range of the measuring instrument.

In this embodiment, in the description of the probe adapter, the measuring instrument 70 and the probe 60 are both placed in a normal operating state, i.e., the measuring instrument 70 is placed horizontally, and an axis of an input port of the measuring instrument 70 is in a horizontal direction. Therefore, the probe 60 and the probe adapter extend in the horizontal direction. Therefore, the first interface 11 and the second interface 12 are respectively located at two ends of the probe adapter in the horizontal direction, which are respectively the left end and the right end in the accompanying drawings.

In this embodiment, the measuring instrument may be an oscilloscope. An oscilloscope is mainly used as an example for description below. It may be understood that the foregoing technical solution may also be used for another instrument similar to an oscilloscope.

It may be understood that the first signal transmission line 21 and the second signal transmission line 22 are configured to be disconnected or non-communicating with each other, which are not limited in structure and position.

The line selection switch is configured to select to electrically connect a signal transmission line that conducts the first interface 11 and the second interface 12, that is, configured to select to electrically connect either of the first signal transmission line 21 and the second signal transmission line 22.

It may be understood that probes used by the measuring instrument have different output impedances. For a high-bandwidth measuring instrument, signal input interfaces are disposed with a low impedance, for example, 50 ohms. Therefore, a probe with a high output impedance, for example, a high impedance passive probe, cannot directly output a signal to the high-bandwidth measuring instrument. Therefore, it is necessary to adjust the impedance of the measured signal through the signal conditioning circuit 24 to match the input impedance of the measuring instrument 70. Meanwhile, an amplitude of a signal with a high impedance generally may exceed the measurement range of the measuring instrument 70. Therefore, it is also necessary to adjust the amplitude of the measured signal through the signal conditioning circuit 24.

For the probe adapter in the embodiment of the present disclosure, two signal transmission lines, namely, the first signal transmission line 21 and the second signal transmission line 22, are disposed between the first interface 11 and the second interface 12 of the probe adapter, and the signal conditioning circuit 24 is disposed on the second signal transmission line 22 and is configured to adjust the impedance and/or the amplitude of the measured signal to correspondingly match the input impedance and/or the measurement range of the measuring instrument. In this way, a high-bandwidth measuring instrument can use an ordinary high impedance passive probe and/or active probe through the probe adapter in this embodiment, and it is not necessary to change probe adapters for different probes.

In some embodiments, referring to FIG. 2, the probe adapter further includes:
a control part 31, configured to control the line selection switch to select the first signal transmission line 21 or the second signal transmission line 22 to conduct the first interface 11 and the second interface 12, where the line selection switch is communicatively connected to the control part 31.

The communicative connection includes a wired connection and a wireless connection. Therefore, the control part 31 may control the line selection switch in a wired manner, or may control the line selection switch in a wireless manner. In addition, a wireless connection manner may also exist between other components. Therefore, it is not necessary for a reader to limit a connection between the components to a direct connection in the accompanying drawings, but instead can determine a relationship between the components based on the textual description herein and the implementation of the functions in the embodiments of the present disclosure.

The line selection switch is an execution part that implements the selection of a signal transmission line by the probe adapter. The execution of the line selection switch is controlled by the control part 31. The control of the execution of the line selection switch by the control part 31 has advantages of high efficiency and being not prone to errors.

It can be understood that the selection by the line selection switch can be controlled through a manual operation.

In some embodiments, the control part 31 is specifically configured to:
acquire a type of the probe 60 connected to the first interface 11, in a case that the type of the probe 60 connected to the first interface 11 is a first probe, control the line selection switch to select the first signal transmission line 21 to conduct the first interface 11 and the second interface 12, and in a case that the type of the probe 60 connected to the first interface 11 is a second probe, control the line selection switch to select the second signal transmission line 22 to conduct the first interface 11 and the second interface 12.

It needs to be noted that an output impedance of the probe 60 has a particular relationship with the measured signal. In one aspect, the type of the probe 60 including the value of the output impedance is selected according to the measured signal. Therefore, different probes 60 indicate different measured signals. In another aspect, after the measured signal passes through the probe 60, a measured value of the measured signal also changes due to an impact of a related parameter, for example, the output impedance, of the probe 60. Therefore, two different signal transmission lines need to be disposed for the probe adapter according to the output impedance of the probe 60, either of which is selected during measurement.

The type of the probe 60 connected to the first interface 11 is acquired first, and then the line selection switch is controlled, so that an action of automatically controlling the line selection switch can be better implemented. In addition, this is also the objective of disposing two or more signal transmission lines, i.e., different signal transmission lines are used to adapt to different probes.

In this embodiment, two signal transmission lines, namely, the first signal transmission line 21 and the second signal transmission line 22, are disposed. However, it can be understood that more signal transmission lines can be disposed.

The type of the probe 60 may include a probe with a low output impedance, a probe with a high output impedance, and the like. It may be understood that probes of other types may further be included. The control part 31 may acquire the type of the probe 60 connected to the first interface 11 by communicatively connecting with the first interface 11.

In some embodiments, the signal conditioning circuit 24 includes:
a gain amplifier 241, configured to adjust the impedance of the measured signal to match the input impedance of the measuring instrument, and/or adjust the amplitude of the measured signal to match the measurement range of the measuring instrument; and
a differential amplifier 242, configured to convert a differential signal outputted by the gain amplifier 241 into a single-ended signal to match a type of the measured signal of the measuring instrument 70.

The gain amplifier 241 has a very high input impedance, low output impedance, and high voltage gain, so that the impedance of the measured signal can be reduced, and the gain of the measured signal can also be increase, making the measurement of the measuring instrument 70 more accurate.

It needs to be noted that the gain amplifier 241 is configured to increase a gain. A signal with the increased gain, i.e., an output signal of the gain amplifier 241, is a differential signal, and a signal that can be measured by the measuring instrument is a single-ended signal. Therefore, the differential amplifier 242 needs to be disposed at an output stage of the gain amplifier 241, and is configured to convert the differential signal outputted by the gain amplifier 241 into the single-ended signal to match the type of the measured signal of the measuring instrument 70.

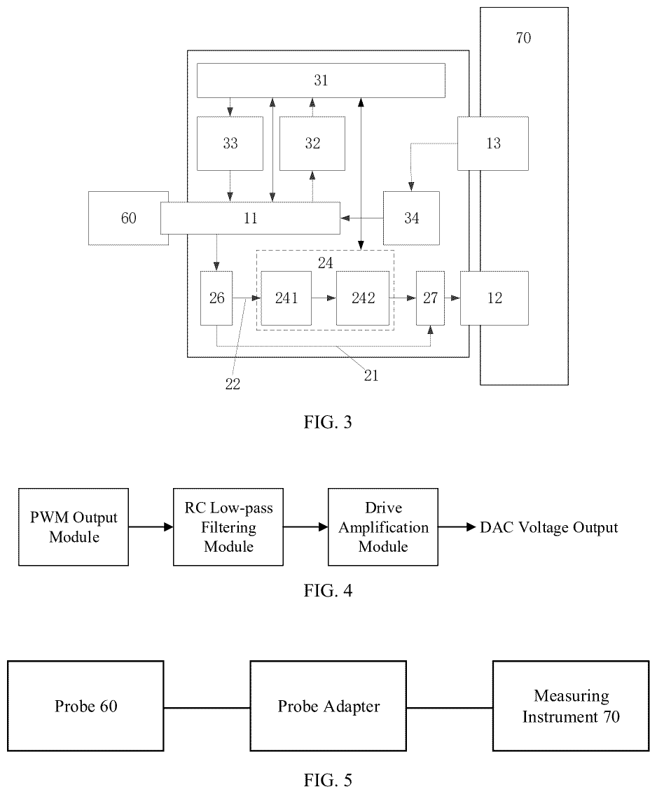

In some embodiments, referring to FIG. 3, the probe adapter further includes:
a recognition circuit 32, communicatively connected to both the control part 31 and the first interface 11, where the recognition circuit 32 is configured to recognize a type of the probe 60 connected to the first interface 11 and send the type to the control part 31.

To be specific, in a case that the probe 60 is inserted into the first interface 11, the recognition circuit 32 may recognize the type of the probe 60, to further send the type of the probe 60 to the control part 31. The control part 31 may control the selection of the line selection switch according to this. The recognition principle of the recognition circuit 32 is not the inventive content of the embodiments of the present disclosure, and details are not described.

In some embodiments, the probe adapter further includes:
a calibration circuit 33, communicatively connected to both the control part 31 and the first interface 11, where the calibration circuit 33 is configured to calibrate an offset of a signal outputted by the probe 60 connected to the first interface 11 and adjust a direct current (DC) component of the measured signal to match a display interface of the measuring instrument 70.

It may be understood that a gain and an offset of an active amplifier inside the active probe may drift due to aging with temperature or time. To compensate for such a drift, it is necessary to calibrate the probe 60 regularly. In the related art, professional equipment is required for calibrating the probe 60, resulting in increased measurement complexity and reduced measurement efficiency. In addition, in the related art, a calibration function is integrated into some probe or measuring instrument. However, in one aspect, the complexity of the probe or measuring instrument is increased, and the costs are increased. In another aspect, calibration efficiency is low. Therefore, in the embodiments of the present disclosure, the calibration circuit 33 is creatively disposed in the probe adapter to add a calibration function of the probe adapter without increasing the complexity of the probe or measuring instrument, so that calibration efficiency is high.

It may be understood that the DC component of the measured signal may not match the display interface of the measuring instrument 70. For example, the amplitude of the measured signal ranges from 0 to 100 V, but on the display interface of the measuring instrument 70, O is a horizontal axis, and is located in the middle of the interface in a vertical direction. Therefore, the measured signal may be offset to −50 V to +50 V through the calibration circuit 33 to match the display interface of the measuring instrument 70.

Similarly, the calibration circuit 33 is creatively disposed in the probe adapter in this embodiment to add an offset function of the probe adapter, so that a display effect of the measuring instrument is improved without adding a corresponding arrangement to a probe or measuring instrument and increasing the complexity of a probe or measuring instrument.

Specifically, the control part 31 may be a microcontroller unit (MCU). The MCU is also referred to as a single chip microcomputer, appropriately reduces the frequency and specifications of a central processing unit (CPU), and integrates memory, a timer, a universal serial bus (USB), analog-to-digital (A/D) converter, a universal asynchronous receiver/transmitter (UART), a programmable logic controller (PLC), direct memory access (DMA), and other peripheral interfaces, and even a liquid crystal display (LCD) driving circuit into a single chip to form a chip-level computer, so as to perform different combinational control for different application scenarios, MCU can be found in various applications, such as mobile phone, personal computer (PC) peripheral, remote control, automotive electronics, industrial stepper motor, and robot arm control, etc.

The recognition circuit 32 and the calibration circuit 33 may be submodules controlled or driven by the MCU. In this way, the implementation of the functions of probe type recognition, calibration, and offset control are more accurate and reliable, and the control of the MCU is also more flexible.

Specifically, the calibration circuit 33 may be a pulse width modulation digital-to-analog converter (PWM-DAC). The PWM-DAC is a common digital signal processing technology, which can convert a digital signal into an analog signal, and can control an amplitude of the outputted analog signal according to a pulse width of the inputted digital signal. As shown in FIG. 4, the PWM-DAC may include a PWM output module, a resistor-capacitor (RC) low-pass filtering module, and a drive amplification module that are sequentially connected. The PWM output module may implement a PWM wave with an adjustable duty cycle through software programming by the single chip microcomputer. In a case that a system power voltage (which is usually 5 V or 3.3 V) is fixed, the duty cycle of the PWM wave determines the value of a DAC voltage output. The RC low-pass filtering module may be configured to filter out a harmonic component of the PWM wave to inhibit ripples in an output voltage. The drive amplification module may be a voltage follower designed using an operational amplifier, and may be configured to improve a driving capability of the output voltage.

Further, the functions of the recognition circuit 32 and the calibration circuit 33 may be integrated into the MCU. In this way, the structure is simpler, and the control is more reliable. To be specific, the recognition circuit 32 and the calibration circuit 33 are not separately disposed, but only the control part 31 is provided, and the functions of the recognition circuit 32 and the calibration circuit 33 are integrated into the control part 31.

Alternatively, the foregoing functions are not integrated into the control part 31. However, the type of the probe 60 may be manually inputted, and the foregoing functions are implemented through an external calibration circuit 33.

In some embodiments, the probe adapter further includes:
a first selection switch 26, including a first fixed end and a first selection end, where the first fixed end is electrically connected to the first interface 11, and the first selection end is electrically connected to one of the signal transmission lines according to an instruction of the control part 31; and
a second selection switch 27, including a second fixed end and a second selection end, where the second fixed end is electrically connected to the second interface 12, and the second selection end is electrically connected to one of the signal transmission lines according to an instruction of the control part 31.

The first selection switch 26 and the second selection switch 27 are respectively disposed at the first interface 11 and the second interface 12 to be electrically connected to the first interface 11 and the second interface 12.

Specifically, selection ends, i.e., the first selection end and the second selection end, of the first selection switch 26 and the second selection switch 27 may be linked. To be specific, the first selection end selects to connect to the first signal transmission line 21, and the second selection switch also selects to connect to the first signal transmission line 21, so that the first interface 11 and the second interface 12 can be conducted. In this way, the control is simpler, and the control part 31 only needs to control either of the first selection switch 26 and the second selection switch 27.

In some embodiments, the first selection switch 26 and/or the second selection switch 27 is an electromagnetic relay.

The electromagnetic relay requires a very small amount of electric energy and has sensitive actions and long service life.

In some embodiments, the probe adapter further includes:
a third interface 13, configured to acquire electric energy of the measuring instrument 70; and
a power supply line, having one end electrically connected to the third interface 13 and the other end electrically connected to the first interface 11 to transmit the electric energy to the probe 60.

It may be understood that the active probe needs to use electric energy. Therefore, the third interface 13 is disposed, and is configured to acquire the electric energy of the measuring instrument 70, and the electric energy is transmitted to the probe 60 through the power supply line. It needs to be noted that in addition to receiving the measured signal, the first interface 11 is further configured to transmit the electric energy to the probe 60.

In addition, the control part 31, the signal conditioning circuit 24, the recognition circuit 32, the calibration circuit 33, and the like of the probe adapter all need to use electric energy. Therefore, the electric energy may be acquired through the third interface 13.

Specifically, the electric energy may be delivered to the control part 31, the signal conditioning circuit 24, the recognition circuit 32, the calibration circuit 33, and the like through the first interface 11. The first interface 11 is electrically connected to the control part 31, the signal conditioning circuit 24, the recognition circuit 32, the calibration circuit 33, and the like. It may be understood that the electrical connection here and the communicative connection between the first interface 11 and the control part 31, the signal conditioning circuit 24, the recognition circuit 32, the calibration circuit 33, and the like described above may use the same line, for example, the same wire.

Specifically, the first interface 11 may be a male interface or a female interface of a bayonet nut connector (BNC), the second interface 12 may be a male interface or a female interface of a radio frequency coaxial connector (e.g., a Sub-Miniature A (SMA) connector, or a 3.5 mm connector, etc.), and the third interface 13 may include a male interface or a female interface of a USB connector (e.g., a USB Type-C), which are not limited thereto.

Specifically, the probe adapter further includes:
a power module 34, having one end electrically connected to the third interface 13 and the other end electrically connected to the first interface 11. The electric energy is delivered to the probe 60, the control part 31, the signal conditioning circuit 24, the recognition circuit 32, the calibration circuit 33, and the like through the first interface 11.

In some embodiments, an output impedance of the first probe is 50 ohms, and an output impedance of the second probe is 1 megohm.

Probes 60 with the two output impedances are relatively common, and have particular universality. Therefore, the probe adapter is disposed according to the two types of probes 60, and can have a large application range.

Embodiments of the present disclosure further provide a measurement system, as shown in FIG. 5, including a measuring instrument 70, a probe 60, and a probe adapter connected between the measuring instrument 70 and the probe 60.

The probe adapter is the probe adapter described above.

According to the measurement system in the embodiment of the present disclosure, two signal transmission lines, namely, the first signal transmission line 21 and the second signal transmission line 22, are disposed between the first interface 11 and the second interface 12 of the probe adapter, and the control part 31 controls the line selection switch to select one of the first signal transmission line 21 and the second signal transmission line 22 to conduct the first interface 11 and the second interface 12. In this way, a high-bandwidth measuring instrument 70 can use an ordinary high impedance passive probe and/or active probe through the foregoing probe adapter, and it is not necessary to change corresponding probe adapters for different probes.

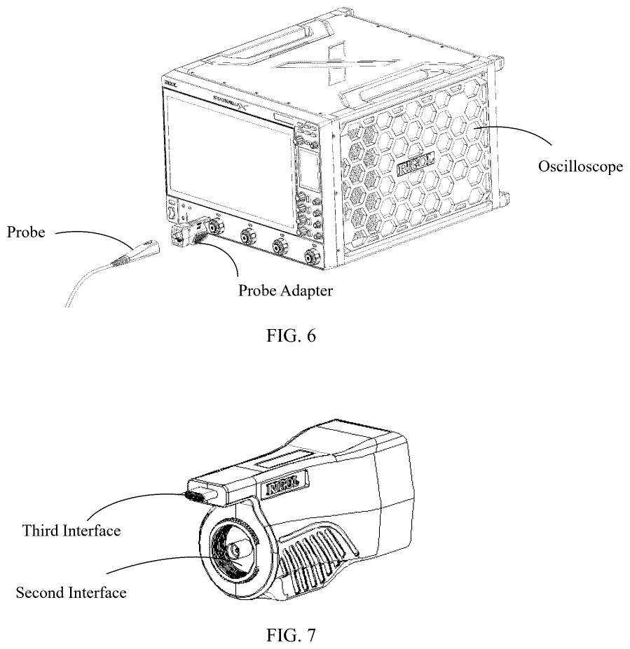

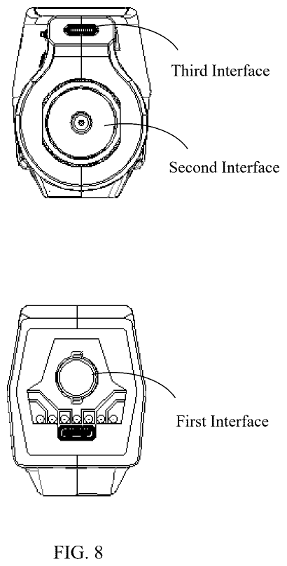

The probe 60 may be a high impedance passive probe and/or active probe. The high impedance passive probe may be a probe that has no active device requiring power supply inside and a relatively high output impedance. For example, for an oscilloscope, a passive probe with an output impedance of about 1 MΩ is a high impedance passive probe. The measuring instrument 70 may be an oscilloscope, a signal analyzer, or the like, but is not limited thereto. For example, FIG. 6 is a schematic structural diagram of a measurement system when a measuring instrument is an oscilloscope. FIG. 7 is a schematic structural diagram of a probe adapter in FIG. 6. FIG. 8 is a schematic structural diagram of a first interface to a third interface in the probe adapter in FIG. 7. The oscilloscope in FIG. 6 may be a high-bandwidth oscilloscope, of which an input channel is a coaxial port with a diameter of 3.5 mm. For a signal analyzer, refer to corresponding descriptions in the related art, and details are not described herein again.

It should be understood that the above embodiments are all exemplary and are not intended to encompass all possible implementations encompassed by the claims. Various variations and changes can also be made on the basis of the above embodiments without departing from the scope of the present disclosure. Similarly, any combination of the various technical features of the above embodiments may be made to form additional embodiments of the present disclosure which may not be expressly described. Therefore, the above embodiments only express several implementations of the present disclosure and do not limit the scope of protection of the present disclosure.

1. A probe adapter, comprising:
a first interface, configured to be electrically connected to a probe to receive a measured signal;
a second interface, configured to be electrically connected to a measuring instrument to input the measured signal into the measuring instrument;
signal transmission lines, comprising a first signal transmission line, a second signal transmission line, and a line selection switch, wherein the first signal transmission line and the second signal transmission line are both located between the first interface and the second interface, and the line selection switch is configured to select the first signal transmission line or the second signal transmission line to conduct the first interface and the second interface; and
a signal conditioning circuit, located on the second signal transmission line, and configured to adjust an impedance of the measured signal to match an input impedance of the measuring instrument, and/or adjust an amplitude of the measured signal to match a measurement range of the measuring instrument.

2. The probe adapter according to claim 1, wherein the probe adapter further comprises:
a control part, configured to control the line selection switch to select the first signal transmission line or the second signal transmission line to conduct the first interface and the second interface, wherein the line selection switch is communicatively connected to the control part.

3. The probe adapter according to claim 2, wherein the control part is specifically configured to:
acquire a type of the probe connected to the first interface, in a case that the type of the probe connected to the first interface is a first probe, control the line selection switch to select the first signal transmission line to conduct the first interface and the second interface, and in a case that the type of the probe connected to the first interface is a second probe, control the line selection switch to select the second signal transmission line to conduct the first interface and the second interface.

4. The probe adapter according to claim 3, wherein an output impedance of the first probe is 50 ohms, and an output impedance of the second probe is 1 megohm.

5. The probe adapter according to claim 2, wherein the probe adapter further comprises:
a recognition circuit, communicatively connected to both the control part and the first interface, wherein the recognition circuit is configured to recognize a type of the probe connected to the first interface and send the type to the control part.

6. The probe adapter according to claim 2, wherein the probe adapter further comprises:
a calibration circuit, communicatively connected to both the control part and the first interface, wherein the calibration circuit is configured to calibrate an offset of a signal outputted by the probe connected to the first interface and adjust a direct current component of the measured signal to match a display interface of the measuring instrument.

7. The probe adapter according to claim 6, wherein the calibration circuit comprises a pulse width modulation output module, a resistor-capacitor low-pass filtering module, and a drive amplification module.

8. The probe adapter according to claim 2, wherein the probe adapter further comprises:
a first selection switch, comprising a first fixed end and a first selection end, wherein the first fixed end is electrically connected to the first interface, and the first selection end is electrically connected to one of the signal transmission lines according to an instruction of the control part; and
a second selection switch, comprising a second fixed end and a second selection end, wherein the second fixed end is electrically connected to the second interface, and the second selection end is electrically connected to one of the signal transmission lines according to an instruction of the control part.

9. The probe adapter according to claim 1, wherein the signal conditioning circuit comprises:
a gain amplifier, configured to adjust the impedance of the measured signal to match the input impedance of the measuring instrument, and/or adjust the amplitude of the measured signal to match the measurement range of the measuring instrument; and
a differential amplifier, configured to convert a differential signal outputted by the gain amplifier into a single-ended signal to match a type of the measured signal of the measuring instrument.

10. The probe adapter according to claim 1, wherein the probe adapter further comprises:
a third interface, configured to acquire electric energy of the measuring instrument; and
a power supply line, having one end electrically connected to the third interface and the other end electrically connected to the first interface to transmit the electric energy to the probe.

11. The probe adapter according to claim 10, wherein the third interface comprises a male interface or a female interface of a universal serial bus connector.

12. The probe adapter according to claim 2, wherein the probe adapter further comprises:
a third interface, configured to acquire electric energy of the measuring instrument; and
a power supply line, having one end electrically connected to the third interface and the other end electrically connected to the first interface to transmit the electric energy to the probe.

13. The probe adapter according to claim 12, wherein the third interface comprises a male interface or a female interface of a universal serial bus connector.

14. The probe adapter according to claim 1, wherein the first interface comprises a male interface or a female interface of a bayonet nut connector.

15. The probe adapter according to claim 1, wherein the second interface comprises a male interface or a female interface of a radio frequency coaxial connector.

16. A measurement system, comprising a measuring instrument, a probe, and a probe adapter connected between the measuring instrument and the probe, wherein
the probe adapter is the probe adapter according to claim 1.

17. The measurement system according to claim 16, wherein the measuring instrument comprises an oscilloscope or a signal analyzer.

18. The measurement system according to claim 16, wherein the probe is a high impedance passive probe or active probe.
